(19) United States
(12) Patent Application Publication
(10) Pub. No.: US 2009/0162976 A1
(43) Pub. Date: Jun. 25, 2009

(54) Method of manufacturing pins of miniaturization chip module

(76) Inventors: Kuan-Hsing Li, Tsao Tuen (TW); Kuo-Hsien Liao, Tsao Tuen (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/003,254

(22) Filed: Dec. 21, 2007

(51) Int. Cl. H01L 21/60

(52) U.S. Cl. 438/123; 257/E21.51

(57) ABSTRACT

A method of manufacturing a miniaturization chip module includes steps of providing a chip module having a substrate, wherein the substrate has a plurality of bonding pads spaced on a rear surface of substrate; providing a lead frame including a plurality of spaced metallic studs, wherein the metallic studs are attached onto the bonding pads; and forming metallic blocks as I/O pins by removing a part of each metallic stud and a part of the lead frame which is not in contact with the substrate.

### BACKGROUND OF THE INVENTION

1. Field of the Invention

The invention generally relates to a method of manufacturing a miniaturization chip module, particularly a method of manufacturing input/output (I/O) pins of a miniaturization chip module.

2. Description of the Related Art

I/O pins for a prior Ball Grid Array (BGA) chip module package are solder balls as shown in FIG. 1. Referring to FIG. 1, a plurality of solder balls is mounted on a lower surface of a main board 81 of a surface mount technology (SMT) chip module 8 as the I/O pins. BGA is widely used because of low manufacturing cost but has some disadvantages. For example the solder balls tend to collapse, causing the difficulty of controlling solder ball height. Besides, the solder balls easily delaminate from the main board 81 or frame they should firmly bonded to, resulting in inferior liability.

Referring to FIG. 2, via-holes in a prior laminated layered carrier board 92 mounted on a bottom of a main board 91 of a SMT chip module 9 respectively have an interconnection 93 as I/O pin. This type of I/O pins cost high and have inferior heat dissipation because the heat is only spread out through the via-holes of the interconnections.

### SUMMARY OF THE INVENTION

It is an object of the invention to provide a method of manufacturing a miniaturization chip module, which improves the shortages of difficulty of controlling solder ball height in BGA solder ball implanting, and furthermore provides improved liability and heat dissipation with lower manufacturing cost.

In order to achieve the above and other objectives, the method of manufacturing a miniaturization chip module according to the invention includes steps of providing a chip module having a substrate, wherein the substrate has a plurality of bonding pads spaced on a rear surface of substrate; providing a lead frame including a plurality of spaced metallic studs, wherein the metallic studs are attached onto the bonding pads; and forming metallic blocks as I/O pins by removing a part of each metallic stud and a part of the lead frame which is not in contact with the substrate.

With formation of the metallic blocks of constant thickness, the prior problems such as collapse of solder balls and difficulty of controlling the ball height encountered in Ball Grid Array (BGA) can be overcome. In addition, the metallic blocks provide improved bonding reliability because their rectangular-column shape has a larger bonding area than solder balls. Furthermore, compared to via-holes in the lamination structure of the carrier board, the metallic blocks have larger thermal conducting areas and therefore offer improved heat dissipation with lower manufacturing cost.

To provide a further understanding of the invention, the following detailed description illustrates embodiments and examples of the invention, this detailed description being provided only for illustration of the invention.

### BRIEF DESCRIPTION OF THE DRAWINGS

FIG. 1 is a perspective view of a prior BGA chip module package;

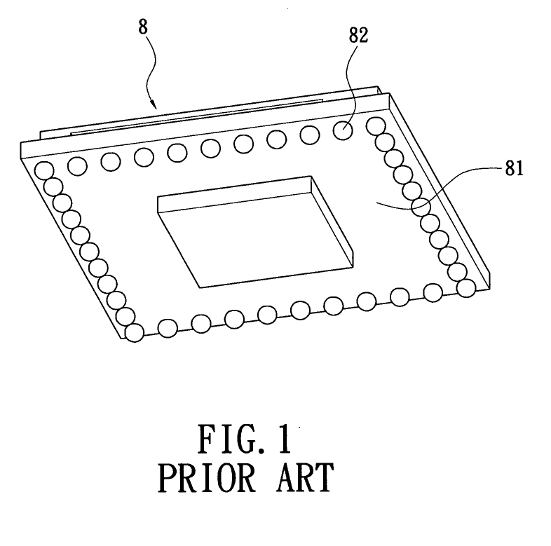

FIG. 2 is a perspective view of a lamination structure of a prior carrier board;

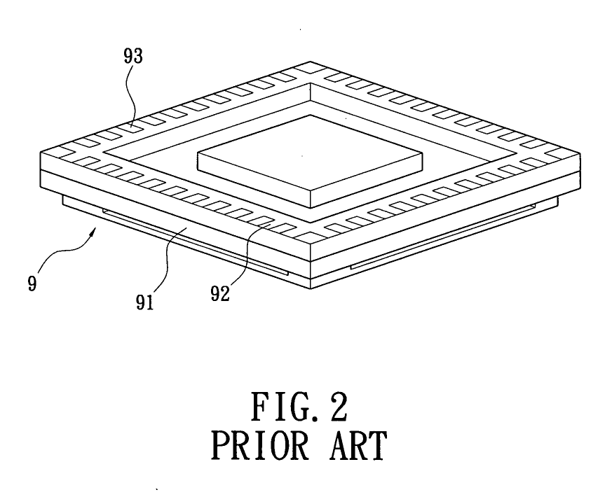

FIG. 3 is a method of manufacturing I/O pins of a chip module according to one embodiment of the invention;

FIG. 4 through FIG. 6 show a method of manufacturing I/O pins of a chip module according to one embodiment of the invention;

FIG. 7 is a perspective view of I/O pins of a chip module according to one embodiment of the invention; and

FIG. 8 is a perspective view of I/O pins of a chip module taken at angle of view different from FIG. 7 according to one embodiment of the invention.

### DETAILED DESCRIPTION OF THE EMBODIMENTS

Wherever possible in the following description, like reference numerals will refer to like elements and parts unless otherwise illustrated.

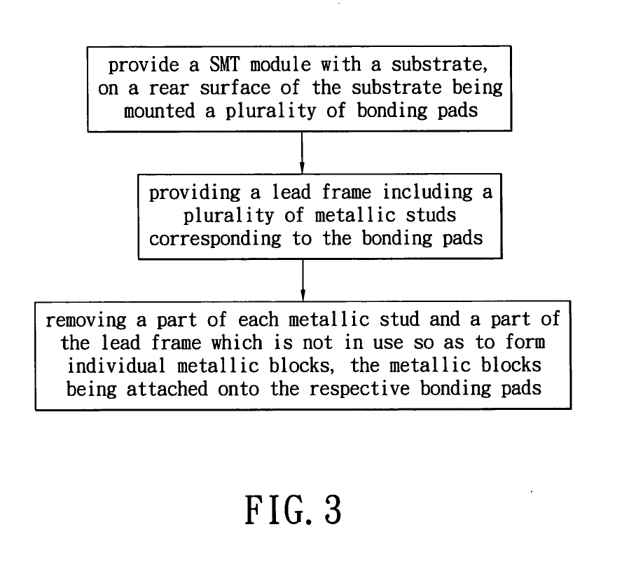

Referring to FIG. 3, according to one embodiment of the invention, a method of manufacturing a miniaturization chip module, particularly a method of manufacturing I/O pins of a miniaturization chip module is shown and will be illustrated in details as below.

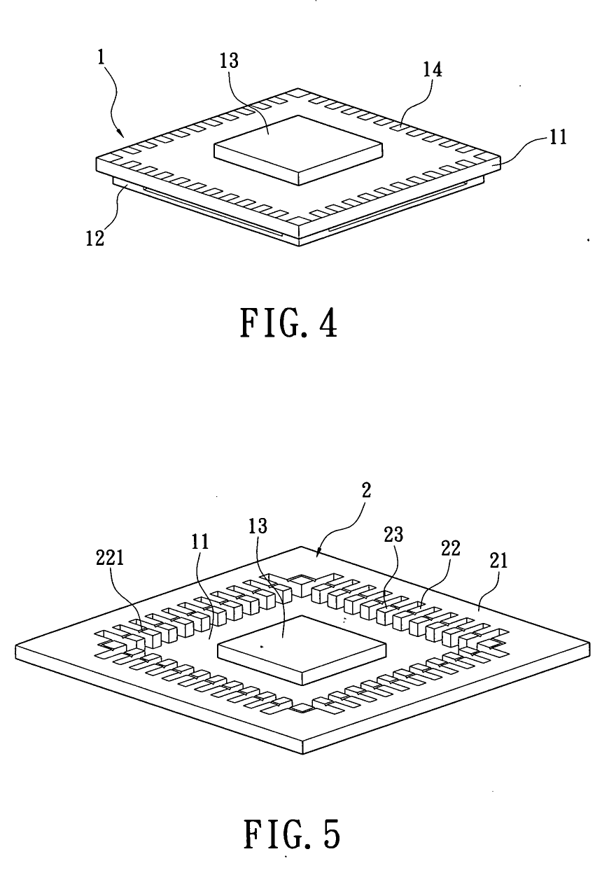

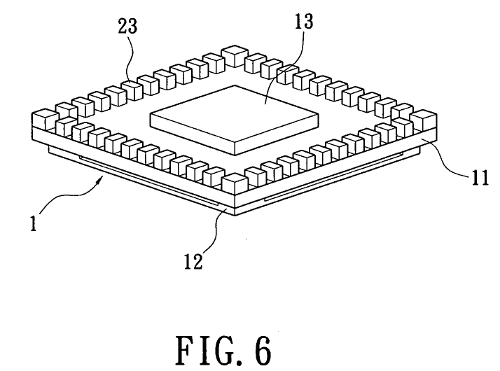

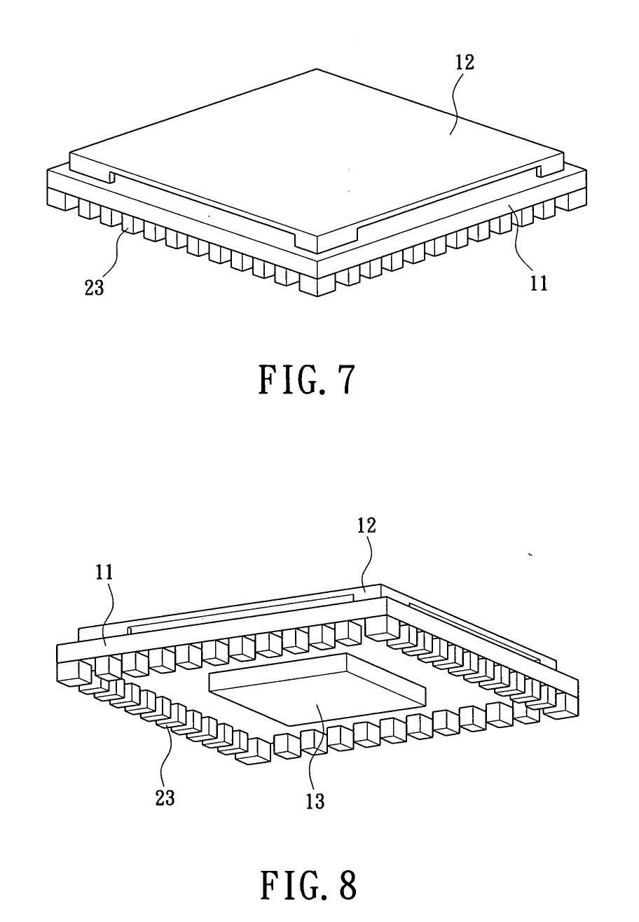

A chip module 1, as shown in FIG. 4, is provided. The chip module is a surface mount technology (SMT) module in this embodiment. The chip module 1 has a substrate 11 on a front surface of which at least one first chip (not shown) and a metal cover 12 (as shown in FIG. 7 and FIG. 8) covering the chip are mounted. The first chip can be a surface-mounting device (SMD) chip for example. The metal cover 12 has bent legs which are welded onto the substrate 11 as a shield of the first chip for providing electromagnetic interference (EMI) effect. On a rear surface of the substrate 11 is mounted a second chip 13 and a plurality of bonding pads 14 spaced disposed along a periphery of a rear surface of the substrate 11 and electrically connected to the second chip 13 disposed on the substrate 11.

Subsequently, a lead frame 2 made of highly electrically conductive material such as copper, tin or steel is provided, as shown in FIG.5. The lead frame 2 in this embodiment is in form of a rectangular shape, but the configuration does not restrict the invention. The lead frame 2 includes a frame body 21 and a plurality of metallic studs 22 extending from a periphery of the frame body 21 toward a center of the frame body 21 on an upper surface of the frame body 21. The lead frame is attached onto the rear surface of the substrate 11 in a manner that the metallic studs 22 are exposed. In this embodiment, the metallic studs 22 are in shape of rectangular column and disposed at intervals to respectively correspond to the bonding pads 14. Each of the metallic studs 22 has a free end distant from the frame body 21. On its exposed surface opposite to the substrate 11 is a cutting groove 221 with a V-shaped profile so that the studs 22 can be easily cut.

The attachment of the substrate 11 to the lead frame 2 can be reached by welding the metallic studs 22 onto the rear surface of the substrate 11 so that the metallic studs 22 are respectively electrically connected to the corresponding bonding pads 14. In other words, the metallic studs 22 are welded or soldered by a SMT process onto the bonding pads 14. There is a vacancy at the center of the lead frame 2 for accommodation of the second chip 13. In order to prevent the second chip 13 from touching a mother board of a host system (not shown), the thickness of the lead frame 2 can be adjusted.

Then, a cutter is used to cut down along the cutting grooves 221 to remove a part of each metallic stud 22 and a part of the lead frame 2 which is not in contact with the substrate 11. In other words, the unnecessary part of the metallic stud 22 and the lead frame 2 will be removed. The remaining metallic studs 22 become individual metallic blocks 23 as shown in FIG. 6, and the metallic blocks 23 are connected with the corresponding bonding pads 14 so as to be used as I/O pins of the chip module 1. In this embodiment, the metallic studs 22 are in shape of rectangular column and therefore the metallic blocks 23 are in shape of rectangular column as well. However, the shapes of the metallic studs 22 and the metallic blocks 23 are not limited to rectangular column.

FIG. 7 and FIG. 8 show that the substrate 11 of the chip module 1 has a plurality of bonding pads 14 spaced along its peripheral edge and respectively welded with metallic blocks 23 which are used as I/O pins of the chip module 1.

Since the lead frame 2 and the metallic blocks 23 respectively have constant thickness, the prior problems such as collapse of solder balls and difficulty of controlling the ball height encountered in Ball Grid Array (BGA) can be overcome. In addition, the metallic blocks 23 provide improved bonding reliability because their rectangular-column shape has a larger bonding area than solder balls. Furthermore, compared to via-holes in the lamination structure of the carrier board, the metallic blocks 23 have larger thermal conducting areas and therefore offer improved heat dissipation with lower manufacturing cost.

It should be apparent to those skilled in the art that the above description is only illustratives of specific embodiments and examples of the invention. The invention should therefore cover various modifications and variations made to the herein-described structure and operations of the invention, provided they fall within the scope of the invention as defined in the following appended claims.

What is claimed is:

1. A method of manufacturing a miniaturization chip module, comprising:
providing a chip module having a substrate, wherein the substrate has a plurality of bonding pads spaced on a rear surface of substrate;
providing a lead frame including a plurality of spaced metallic studs, wherein the metallic studs are attached onto the bonding pads; and
forming metallic blocks as I/O pins by removing a part of each metallic stud and a part of the lead frame wherein the metallic blocks are connected with the bonding pads.

2. The method of claim 1, wherein the bonding pads are disposed along a periphery of the rear surface of the substrate.

3. The method of claim 1, wherein the lead frame includes a frame body and the metallic studs extend from the periphery of the frame body toward a center of the lead frame, each of the metallic studs has a free end distant from the frame body.

4. The method of claim 1, wherein the metallic studs are in shape of rectangular column, and the metallic blocks are in shape of rectangular column.

5. The method of claim 1, wherein the metallic studs are welded onto the bonding pads.

6. The method of claim 1, wherein the metallic studs are soldered by a surface-mounting technology (SMT) process onto the bonding pads.

7. The method of claim 1, wherein the metallic studs respectively have a cutting groove along which the lead frame is cut to form the metallic blocks.

8. The method of claim 1, wherein the chip module is a surface-mounting device (SMD).
